(19) United States
(12) Patent Application Publication
(10) Pub. No.: US 2025/0203981 A1
(43) Pub. Date: Jun. 19, 2025

(54) SEMICONDUCTOR DEVICE

(71) Applicant: Renesas Electronics Corporation, Tokyo (JP)

(72) Inventors: Takeshi TODA, Tokyo (JP); Yasutaka NAKASHIBA, Tokyo (JP)

(21) Appl. No.: 18/928,306

(22) Filed: Oct. 28, 2024

(30) Foreign Application Priority Data
Dec. 14, 2023 (JP) 2023-210817

(51) Int. Cl. H01L 29/10; H01L 29/735; H01L 29/78

(52) U.S. Cl. CPC H10D 62/371; H10D 10/60; H10D 30/65

(57) ABSTRACT

A semiconductor device includes a dummy field structure in a non-element forming region. The dummy field structure includes a deep n-type well, an n-type well, a trench, a conductor layer, a first n-type semiconductor region, a second n-type semiconductor region, and a third n-type semiconductor region. The semiconductor device includes not only a first parasitic bipolar transistor but also a second parasitic bipolar transistor.

### CROSS-REFERENCE TO RELATED APPLICATION

The disclosure of Japanese Patent Application No. 2023-210817 filed on Dec. 14, 2023, including the specification, drawings and abstract is incorporated herein by reference in its entirety.

### BACKGROUND

The present invention relates to a semiconductor device, and relates to a technique effectively applicable to, for example, a semiconductor device including an element forming region and a non-element forming region.

There is disclosed technique listed below.
[Patent Document 1] Japanese Unexamined Patent Application Publication No. 2017-117882

The Patent Document 1 describes a technique for a semiconductor device including an active barrier structure.

For example, in a semiconductor device connected to a circuit including an inductor, a parasitic bipolar transistor may be operated by noise based on back electromotive force. In this case, by the operation of the parasitic bipolar transistor, a potential of the circuit is modulated. Consequently, an operation failure may be caused in the circuit. Thus, a technique for suppressing the operation of the parasitic bipolar transistor is desired in order to suppress the operation failure in the circuit.

Other objects and novel characteristics will become apparent from the description of the present specification and the drawings.

A semiconductor device according to one embodiment includes a dummy field structure formed in a non-element forming region. The dummy field structure functions as a collector of the parasitic bipolar transistor. The dummy field structure includes a stacked structure of an n-type semiconductor region which is formed in the non-element forming region and to which a fixed potential is supplied.

According to one embodiment, performance of a semiconductor device can be improved.

### BRIEF DESCRIPTIONS OF THE DRAWINGS

FIG. 1 is a diagram illustrating a configuration of a semiconductor device including a p-type LDMOSFET.

FIG. 2 is a diagram illustrating a configuration of a semiconductor device including an npn-type bipolar transistor.

FIG. 3 is a diagram illustrating a configuration of a semiconductor device including a lateral pnp-type bipolar transistor.

FIG. 4 is a diagram illustrating a stacked structure.

FIG. 5 is a diagram for explaining the first related art.

FIG. 6 is a diagram for explaining the second related art.

FIG. 7 is a diagram for explaining a basic concept of an embodiment.

FIG. 8 is a diagram illustrating a configuration of a semiconductor device according to a typified aspect.

FIG. 9 is a plan view illustrating a positional relationship between an element forming region and a non-element forming region.

FIG. 10 is a plan view illustrating a part of the non-element forming region.

FIG. 11 is a cross-sectional view taken along the line A-A of FIG. 10.

FIG. 12 is a cross-sectional view taken along the line B-B of FIG. 10.

FIG. 13 is a graph illustrating a relationship between a distance and “α” according to a typified aspect.

FIG. 14 is a plan view illustrating a configuration of a semiconductor device according to an application example.

FIG. 15 is a cross-sectional view taken along the line A-A of FIG. 14.

FIG. 16 is a cross-sectional view taken along the line B-B of FIG. 14.

### SUMMARY

The same components are denoted by the same reference symbols in principle throughout all the drawings for describing the embodiments, and the repetitive description thereof will be omitted. Also, hatching is used even in a plan view so as to make the drawings easy to see.

Elements such as transistors are formed in an “element forming region” in the present specification. That is, the elements configuring a circuit are formed in the “element forming region.” The elements such as transistors are not formed in a “non-element forming region” in the present specification. That is, the elements configuring the circuit are not formed in the “non-element forming region.”

### Exemplary Transistor Configuration

A p-type lateral diffused metal oxide semiconductor field effect transistor (LDMOSFET), an npn-type bipolar transistor, and a lateral pnp-type bipolar transistor among a plurality of types of transistors will be exemplified below.

### Configuration of P-Type Ldmosfet

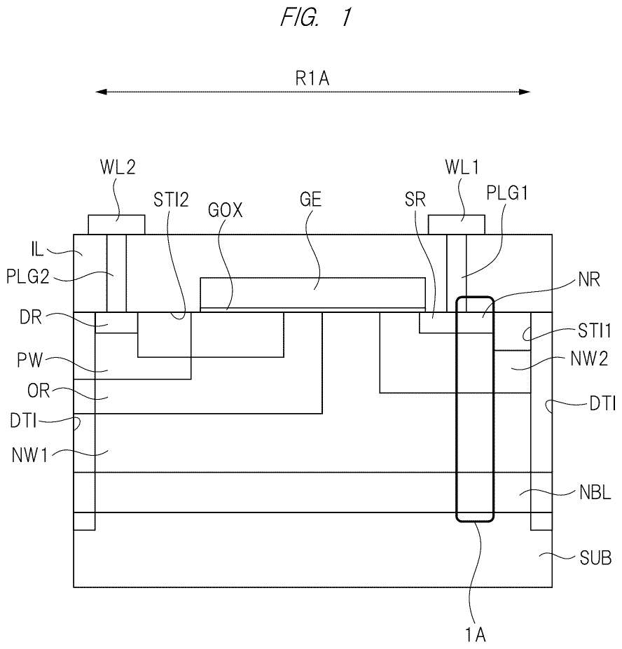

In FIG. 1, a semiconductor device includes a p-type semiconductor substrate SUB, an n-type buried layer NBL, an n-type well NW1, an n-type well NW2, a p-type offset region OR, a p-type well PW, an n-type semiconductor region NR, a source region SR, a drain region DR, a gate insulating film GOX, and a gate electrode GE. The semiconductor device further includes a deep trench DTI, a trench STI1, a trench STI2, an interlayer insulating film IL, a plug PLG1, a plug PLG2, a source wiring WL1, and a drain wiring WL2.

For example, the p-type semiconductor substrate SUB is doped with boron (B) as an acceptor. The concentration of boron is, for example, equal to or higher than 0.3×10¹⁶ (1/cm³) and equal to or lower than 2.0×10¹⁶ (1/cm³).

As illustrated in FIG. 1, the n-type buried layer NBL is formed in the p-type semiconductor substrate SUB. The n-type well NW1 is formed on the n-type buried layer NBL. The n-type well NW1 is formed in a p-type epitaxial layer. The n-type buried layer NBL may be formed in the p-type epitaxial layer. The deep trench DTI penetrates through the n-type well NW1 and the n-type buried layer NBL. The deep trench DTI has a bottom surface in the p-type semiconductor substrate SUB. An insulating material such as silicon oxide is buried in the deep trench DTI.

Although not illustrated in FIG. 1, the deep trench DTI is formed to surround an element forming region R1A in plan view. In other words, the element forming region R1A is surrounded by the deep trench DTI in plan view.

The n-type well NW2 and the p-type offset region OR are formed in the n-type well NW1. As illustrated in FIG. 1, the n-type well NW2 and the p-type offset region OR are separated from each other. The n-type well NW2 is in contact with the deep trench DTI and the trench STI1. An insulating material such as silicon oxide is buried in the trench STI1. The bottom surface of the trench STI1 is positioned in the n-type well NW2.

The n-type semiconductor region NR and the source region SR are formed in the n-type well NW2. The n-type semiconductor region NR is in contact with the trench STI1 and the source region SR. The impurity concentration of the n-type semiconductor region NR is higher than the impurity concentration of the n-type well NW2. The source region SR is configured of a p-type semiconductor region.

As illustrated in FIG. 1, the p-type offset region OR includes the trench STI2. An insulating material such as silicon oxide is buried in the trench STI2. The bottom surface of the trench STI2 is positioned in the p-type offset region OR or the p-type well PW. The p-type well PW is formed in the p-type offset region OR. The p-type well PW is in contact with the trench STI2. The impurity concentration of the p-type well PW is higher than the impurity concentration of the p-type offset region OR. The drain region DR is formed in the p-type well PW. The drain region DR is in contact with the deep trench DTI and the trench STI2. The impurity concentration of the drain region DR is higher than the impurity concentration of the p-type well PW. The drain region DR is configured of a p-type semiconductor region.

The source region SR is formed to be shallower than the bottom surface of the trench STI1. The drain region DR is formed to be shallower than the bottom surface of the trench STI2.

The gate electrode GE is formed, via the gate insulating film GOX, on a part of the source region SR, a part of the n-type well NW2, a part of the n-type well NW1, a part of the p-type offset region OR, and a part of the trench STI2.

The interlayer insulating film IL is formed on the deep trench DTI, the trench STI1, the trench STI2, the source region SR, and the drain region DR to cover the gate electrode GE. The interlayer insulating film IL is made of, for example, a silicon oxide film. As illustrated in FIG. 1, the plug PLG1 and the plug PLG2 are formed in the interlayer insulating film IL.

The plug PLG1 penetrates through the interlayer insulating film IL and is in contact with the source region SR and the n-type semiconductor region NR. That is, the plug PLG1 is electrically connected to the source region SR and the n-type semiconductor region NR. The plug PLG2 penetrates through the interlayer insulating film IL and is in contact with the drain region DR. That is, the plug PLG2 is electrically connected to the drain region DR.

The source wiring WL1 and the drain wiring WL2 are formed on the interlayer insulating film IL. The source wiring WL1 is connected to the plug PLG1. Thus, the source wiring WL1 is electrically connected to the source region SR and the n-type semiconductor region NR via the plug PLG1. The drain wiring WL2 is connected to the plug PLG2. Thus, the drain wiring WL2 is electrically connected to the drain region DR via the plug PLG2.

The semiconductor device including the p-type LDMOSFET is formed as described above.

The semiconductor device includes a stacked structure 1A. The stacked structure 1A is illustrated as a region surrounded with a thick line in FIG. 1. The stacked structure 1A is configured of the n-type buried layer NBL, the n-type well NW1, the n-type well NW2, and the n-type semiconductor region NR (n-type body contact region). As described later, the stacked structure 1A configures a parasitic bipolar transistor. In the present specification, attention is paid to a parasitic bipolar transistor which causes an operation failure in a circuit.

Therefore, the stacked structure 1A included in the p-type LDMOSFET is clearly described.

### Configuration of Npn-Type Bipolar Transistor

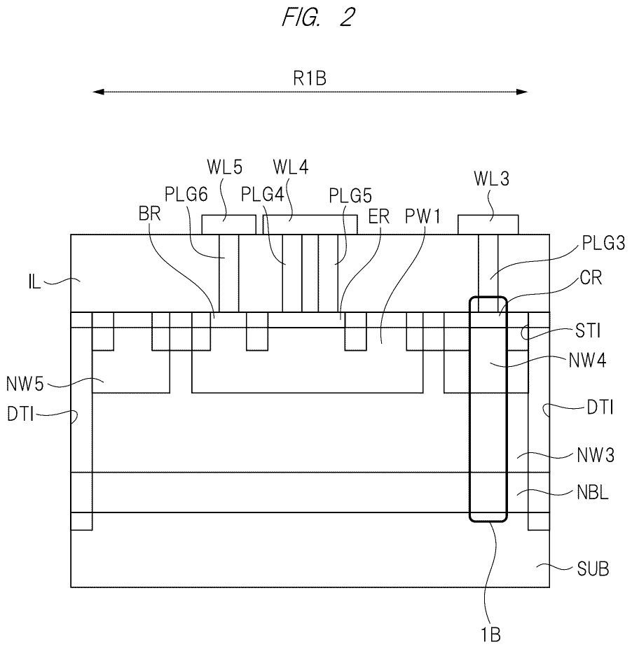

In FIG. 2, the semiconductor device includes the p-type semiconductor substrate SUB, the n-type buried layer NBL, an n-type well NW3, an n-type well NW4, an n-type well NW5, a p-type well PW1, a collector region CR, an emitter region ER, and a base region BR. The semiconductor device further includes the deep trench DTI, the trench STI, the interlayer insulating film IL, a plug PLG3, a plug PLG4, a plug PLG5, a plug PLG6, a collector wiring WL3, an emitter wiring WL4, and a base wiring WL5.

As illustrated in FIG. 2, the n-type buried layer NBL is formed in the p-type semiconductor substrate SUB. The n-type well NW3 is formed on the n-type buried layer NBL. The n-type well NW3 is formed in a p-type epitaxial layer. The n-type buried layer NBL may be formed in the p-type epitaxial layer. The deep trench DTI penetrates through the n-type well NW3 and the n-type buried layer NBL. The deep trench DTI has a bottom surface in the p-type semiconductor substrate SUB. An insulating material such as silicon oxide is buried in the deep trench DTI.

Although not illustrated in FIG. 2, the deep trench DTI is formed to surround an element forming region R1B in plan view. In other words, the element forming region R1B is surrounded by the deep trench DTI in plan view.

The n-type well NW4, the p-type well PW1, and the n-type well NW5 are formed in the n-type well NW3. The n-type well NW4, the p-type well PW1, and the n-type well NW5 are separated from each other. The trench STI is surrounded by the deep trench DTI. An insulating material such as silicon oxide is buried in the trench STI. The bottom surface of the trench STI is positioned in the n-type well NW3, the n-type well NW4, the p-type well PW1, or the n-type well NW5.

The collector region CR is formed in the n-type well NW4. The collector region CR is in contact with the trench STI. The collector region CR is formed to be shallower than the bottom surface of the trench STI. The collector region CR is configured of an n-type semiconductor region. The impurity concentration of the collector region CR is higher than the impurity concentration of the n-type well NW4.

The emitter region ER and the base region BR are formed in the p-type well PW1. The emitter region ER and the base region BR are in contact with the trench STI. The emitter region ER and the base region BR are formed to be shallower than the bottom surface of the trench STI. The emitter region ER is configured of an n-type semiconductor region. The base region BR is configured of a p-type semiconductor region. The impurity concentration of the base region BR is higher than the impurity concentration of the p-type well PW1.

The interlayer insulating film IL is formed on the deep trench DTI, the trench STI, the collector region CR, the emitter region ER, and the base region BR.

The interlayer insulating film IL is made of, for example, a silicon oxide film. As illustrated in FIG. 2, the plug PLG3, the plug PLG4, the plug PLG5, and the plug PLG6 are formed in the interlayer insulating film IL. The plug PLG3 penetrates through the interlayer insulating film IL and is in contact with the collector region CR. That is, the plug PLG3 is electrically connected to the collector region CR. The plug PLG4 and the plug PLG5 penetrate through the interlayer insulating film IL and are in contact with the emitter region ER. That is, the plug PLG4 and the plug PLG5 are electrically connected to the emitter region ER. The plug PLG6 penetrates through the interlayer insulating film IL and is in contact with the base region BR. That is, the plug PLG6 is electrically connected to the base region BR.

The collector wiring WL3, the emitter wiring WL4, and the base wiring WL5 are formed on the interlayer insulating film IL. The collector wiring WL3 is connected to the plug PLG3. Thus, the collector wiring WL3 is electrically connected to the collector region CR via the plug PLG3. The emitter wiring WL4 is connected to the plug PLG4 and the plug PLG5. Thus, the emitter wiring WL4 is electrically connected to the emitter region ER via the plug PLG4 and the plug PLG5. The base wiring WL5 is connected to the plug PLG6. Thus, the base wiring WL5 is electrically connected to the base region BR via the plug PLG6.

The semiconductor device including the npn-type bipolar transistor is formed as described above.

The semiconductor device includes a stacked structure 1B. The stacked structure 1B is illustrated as a region surrounded with a thick line in FIG. 2. The stacked structure 1B is configured of the n-type buried layer NBL, the n-type well NW3, the n-type well NW4, and the collector region CR. As described later, the stacked structure 1B configures a parasitic bipolar transistor. In the present specification, attention is paid to a parasitic bipolar transistor which causes an operation failure in a circuit. Therefore, the stacked structure 1B included in the npn-type bipolar transistor is clearly described.

### Configuration of Lateral Pnp-Type Bipolar Transistor

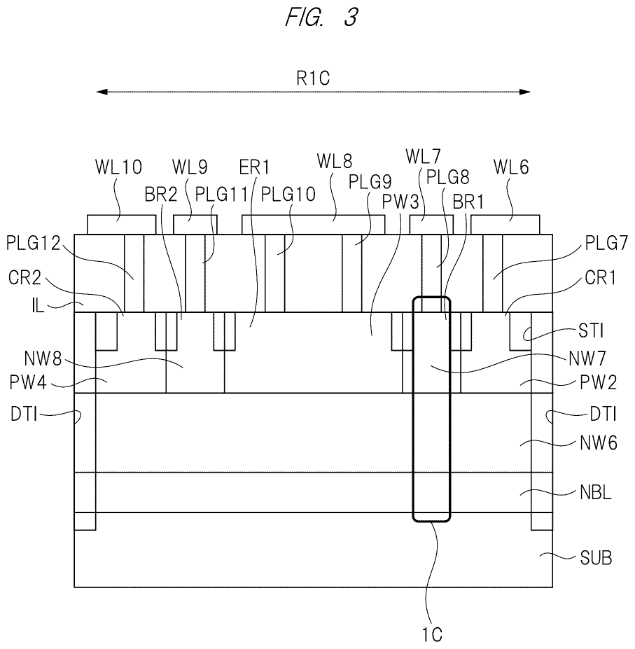

In FIG. 3, the semiconductor device includes the p-type semiconductor substrate SUB, the n-type buried layer NBL, an n-well NW6, a p-type well PW2, an n-type well NW7, a p-type well PW3, an n-type well NW8, a p-type well PW4, a collector region CR1, a base region BR1, an emitter region ER1, a base region BR2, and a collector region CR2. The semiconductor device further includes the deep trench DTI, the trench STI, the interlayer insulating film IL, a plug PLG7, a plug PLG8, a plug PLG9, a plug PLG10, a plug PLG11, a plug PLG12, a collector wiring WL6, a base wiring WL7, an emitter wiring WL8, a base wiring WL9, and a collector wiring WL10.

As illustrated in FIG. 3, the n-type buried layer NBL is formed in the p-type semiconductor substrate SUB. The n-type well NW6 is formed on the n-type buried layer NBL. The n-type well NW6 is formed in a p-type epitaxial layer. The n-type buried layer NBL may be formed in the p-type epitaxial layer. The deep trench DTI penetrates through the n-type well NW6 and the n-type buried layer NBL. The deep trench DTI has a bottom surface in the p-type semiconductor substrate SUB. An insulating material such as silicon oxide is buried in the deep trench DTI.

Although not illustrated in FIG. 3, the deep trench DTI is formed to surround an element forming region R1C in plan view. In other words, the element forming region R1C is surrounded by the deep trench DTI in plan view.

The p-type well PW2, the n-type well NW7, the p-type well PW3, the n-type well NW8, and the p-type well PW4 are formed in the n-type well NW6. The p-type well PW2, the n-type well NW7, the p-type well PW3, the n-type well NW8, and the p-type well PW4 are in contact with each other. The trench STI is surrounded by the deep trench DTI. An insulating material such as silicon oxide is buried in the trench STI. The bottom surface of the trench STI is positioned in the p-type well PW2, the n-type well NW7, the p-type well PW3, the n-type well NW8, or the p-type well PW4.

The collector region CR1 is formed in the p-type well PW2. The collector region CR1 is in contact with the trench STI. The collector region CR1 is formed to be shallower than the bottom surface of the trench STI. The collector region CR1 is configured of a p-type semiconductor region. The impurity concentration of the collector region CR1 is higher than the impurity concentration of the p-type well PW2.

The base region BR1 is formed in the n-type well NW7. The base region BR1 is in contact with the trench STI. The base region BR1 is formed to be shallower than the bottom surface of the trench STI. The base region BR1 is configured of an n-type semiconductor region. The impurity concentration of the base region BR1 is higher than the impurity concentration of the n-type well NW7.

The emitter region ER1 is formed in the p-type well PW3. The emitter region ER1 is in contact with the trench STI. The emitter region ER1 is formed to be shallower than the bottom surface of the trench STI. The emitter region ER1 is configured of a p-type semiconductor region. The impurity concentration of the emitter region ER1 is higher than the impurity concentration of the p-type well PW3.

The base region BR2 is formed in the n-type well NW8. The base region BR2 is in contact with the trench STI. The base region BR2 is formed to be shallower than the bottom surface of the trench STI. The base region BR2 is configured of an n-type semiconductor region. The impurity concentration of the base region BR2 is higher than the impurity concentration of the n-type well NW8.

The collector region CR2 is formed in the p-type well PW4. The collector region CR2 is in contact with the trench STI. The collector region CR2 is formed to be shallower than the bottom surface of the trench STI. The collector region CR2 is configured of a p-type semiconductor region. The impurity concentration of the collector region CR2 is higher than the impurity concentration of the p-type well PW4.

The interlayer insulating film IL is formed on the deep trench DTI, the trench STI, the collector region CR1, the base region BR1, the emitter region ER1, the base region BR2, and the collector region CR2.

The interlayer insulating film IL is made of, for example, a silicon oxide film. As illustrated in FIG. 3, the plug PLG7, the plug PLG8, the plug PLG9, the plug PLG10, the plug PLG11, and the plug PLG12 are formed in the interlayer insulating film IL.

The plug PLG7 penetrates through the interlayer insulating film IL and is in contact with the collector region CR1. That is, the plug PLG7 is electrically connected to the collector region CR1. The plug PLG8 penetrates through the interlayer insulating film IL and is in contact with the base region BR1. That is, the plug PLG8 is electrically connected to the base region BR1. The plug PLG9 and the plug PLG10 penetrate through the interlayer insulating film IL and are in contact with the emitter region ER1. That is, the plug PLG9 and the plug PLG10 are electrically connected to the emitter region ER1. The plug PLG11 penetrates through the interlayer insulating film IL and is in contact with the base region BR2. That is, the plug PLG11 is electrically connected to the base region BR2. The plug PLG12 penetrates through the interlayer insulating film IL and is in contact with the collector region CR2. That is, the plug PLG12 is electrically connected to the collector region CR2.

The collector wiring WL6, the base wiring WL7, the emitter wiring WL8, the base wiring WL9, and the collector wiring WL10 are formed on the interlayer insulating film IL.

The collector wiring WL6 is connected to the plug PLG7. Thus, the collector wiring WL6 is electrically connected to the collector region CR1 via the plug PLG7. The base wiring WL7 is connected to the plug PLG8. Thus, the base wiring WL7 is electrically connected to the base region BR1 via the plug PLG8. The emitter wiring WL8 is connected to the plug PLG9 and the plug PLG10. Thus, the emitter wiring WL8 is electrically connected to the emitter region ER1 via the plug PLG9 and the plug PLG10. The base wiring WL9 is connected to the plug PLG11. Thus, the base wiring WL9 is electrically connected to the base region BR2 via the plug PLG11. The collector wiring WL10 is connected to the plug PLG12. Thus, the collector wiring WL10 is electrically connected to the collector region CR2 via the plug PLG12.

The semiconductor device including the lateral pnp-type bipolar transistor is formed as described above.

The semiconductor device includes a stacked structure 1C. The stacked structure 1C is illustrated as a region surrounded with a thick line in FIG. 3. The stacked structure 1C is configured of the n-type buried layer NBL, the n-type well NW6, the n-type well NW7, and the base region BR1. As described later, the stacked structure 1C configures a parasitic bipolar transistor. In the present specification, attention is paid to a parasitic bipolar transistor which causes an operation failure in a circuit. Therefore, the stacked structure 1C included in the lateral pnp-type bipolar transistor is clearly described.

### Configuration of Stacked Structure

The stacked structure 1A of FIG. 1, the stacked structure 1B of FIG. 2, and the stacked structure 1C of FIG. 3 have a common configuration. The common configuration among the stacked structure 1A, the stacked structure 1B, and the stacked structure 1C is expressed as a stacked structure 10 in the present specification. That is, in the following description, an embodiment will be described with reference to the stacked structure 10.

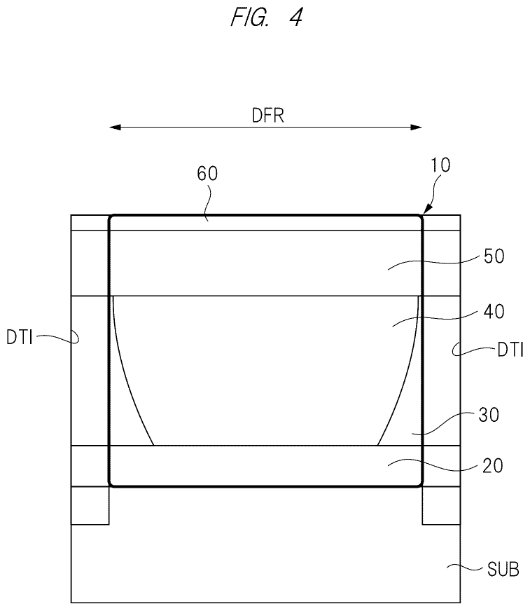

FIG. 4 illustrates the p-type semiconductor substrate SUB, the deep trench DTI, and the stacked structure 10. As illustrated in FIG. 4, the stacked structure 10 is formed on the p-type semiconductor substrate SUB. The stacked structure 10 is surrounded by the deep trench DTI.

The stacked structure 10 includes an n-type buried layer 20, a deep n-type well 40, an n-type well 50, and an n-type diffusion layer 60. The n-type buried layer 20 is formed in the p-type semiconductor substrate SUB. A p-type epitaxial layer 30 is formed on the n-type buried layer 20. The n-type buried layer 20 may be formed in the p-type epitaxial layer 30.

The deep n-type well 40, the n-type well 50, and the n-type diffusion layer 60 are formed in the p-type epitaxial layer 30. The n-type well 50 is formed on the deep n-type well 40. The n-type diffusion layer 60 is formed on the n-type well 50.

The region surrounded by the deep trench DTI is an element forming region DFR. Specifically, FIG. 4 illustrates the stacked structure 10 in the element forming region DFR surrounded by the deep trench DTI. For example, the n-type diffusion layer 60 in the stacked structure 10 corresponds to the n-type semiconductor region NR (n-type body contact region) in the stacked structure 1A, the collector region CR in the stacked structure 1B, or the base region BR1 in the stacked structure 1C.

In order to pay the attention to the stacked structure of the transistor formed in the element forming region in the present specification, FIG. 4 illustrates, for example, the stacked structure 10 in the element forming region DFR surrounded by the deep trench DTI.

### DESCRIPTION OF FIRST RELATED ART

The “first related art” in the present specification is not a publicly-known technique but a technique having a problem found by the present inventors and being a precondition of the present disclosure.

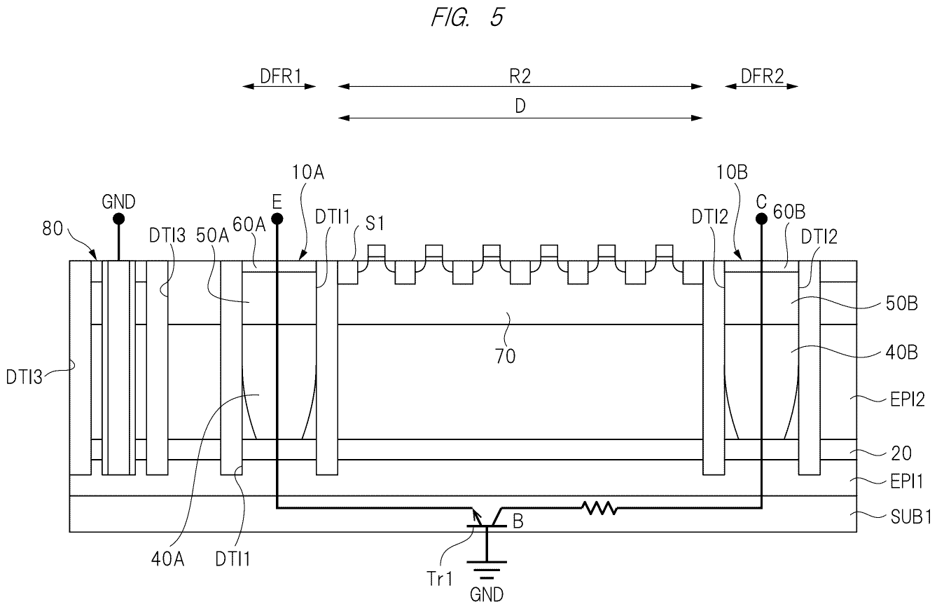

In FIG. 5, a semiconductor device according to the first related art includes a p-type semiconductor substrate SUB1, a p-type epitaxial layer EPI1, the n-type buried layer 20, a p-type epitaxial layer EPI2, a p-type well 70, a deep trench DTI1, a deep trench DTI2, a deep trench DTI3, a stacked structure 10A, a stacked structure 10B, and a GND structure 80.

As illustrated in FIG. 5, the semiconductor device includes an element forming region DFR1, an element forming region DFR2, and a non-element forming region R2. The element forming region DFR1 is surrounded by the deep trench DTI1. The stacked structure 10A is formed in the element forming region DFR1. The element forming region DFR2 is surrounded by the deep trench DTI2. The stacked structure 10B is formed in the element forming region DFR2.

The stacked structure 10A includes the n-type buried layer 20, a deep n-type well 40A, an n-type well 50A, and an n-type diffusion layer 60A. The stacked structure 10B includes the n-type buried layer 20, a deep n-type well 40B, an n-type well 50B, and an n-type diffusion layer 60B.

The GND structure 80 is formed to be surrounded by the deep trench DTI3. As illustrated in FIG. 5, the GND structure 80 includes a trench reaching from an upper surface S1 of the p-type epitaxial layer EPI2 to the p-type epitaxial layer EPI1, and a conductive material (such as polysilicon) buried in the trench. Thereby, a GND potential (0 V) can be supplied to the p-type epitaxial layer EPI1 and the p-type semiconductor substrate SUB1. That is, the GND structure 80 has a function to supply the GND potential to the p-type semiconductor substrate SUB1.

The deep n-type well 40A, the deep n-type well 40B, the n-type well 50A, the n-type well 50B, the n-type diffusion layer 60A, the n-type diffusion layer 60B, the p-type well 70, the deep trench DTI1, the deep trench DTI2, and the deep trench DTI3 are formed in the p-type epitaxial layer EPI2.

The p-type semiconductor substrate SUB1 is doped with a p-type impurity (acceptor). For example, the p-type semiconductor substrate SUB1 is doped with boron (B) as the acceptor. The concentration of boron is, for example, equal to or higher than 0.5×10¹⁹ (1/cm³) and equal to or lower than 4.0×10¹⁹ (1/cm³).

### Parasitic Bipolar Transistor

For example, the stacked structure 10A is a component of the transistor formed in the element forming region DFR1. It is assumed herein that the semiconductor device is connected to a circuit including an inductor. It is particularly assumed that negative potential noise caused by back electromotive force produced in the inductor is transmitted to the stacked structure 10A of the transistor.

In this case, negative potential noise is input into the stacked structure 10A. The GND potential is supplied from the GND structure 80 to the p-type semiconductor substrate SUB1 and the p-type epitaxial layer EPI1. Thus, when negative potential noise is input into the stacked structure 10A, a pn junction formed by the stacked structure 10A and the p-type epitaxial layer EPI1 is forward biased. Consequently, current flows from the p-type semiconductor substrate SUB1 to the stacked structure 10A via the p-type epitaxial layer EPI1. In other words, electrons flow from the stacked structure 10A to the p-type semiconductor substrate SUB1 via the p-type epitaxial layer EPI1.

As illustrated in FIG. 5, the stacked structure 10A, the p-type semiconductor substrate SUB1, and the stacked structure 10B configure a parasitic bipolar transistor Tr1 (npn-type bipolar transistor). The stacked structure 10A configures an emitter, the p-type semiconductor substrate SUB1 configures a base, and the stacked structure 10B configures a collector. Thus, emitter current flows from the p-type semiconductor substrate SUB1 to the stacked structure 10A. When a base-emitter voltage caused when the emitter current flows through a base resistance exceeds a predetermined voltage, collector current flows from the stacked structure 10B to the stacked structure 10A via the p-type semiconductor substrate SUB1. In other words, electrons flow into the stacked structure 10B. Consequently, the potential of the circuit including the stacked structure 10B is modulated. Thus, the operation failure in the circuit can be caused in the semiconductor device according to the first related art.

The phenomenon that is the operation of the parasitic bipolar transistor Tr1 as described above is called “substrate injection.” A ratio between the emitter current and the collector current in the parasitic bipolar transistor Tr1 (collector current/emitter current) is called “α.” The smaller the “α” is, the higher the performance of the semiconductor device is. For example, the larger the distance D of FIG. 5 is, the smaller the “α” is. However, the large distance D means a large size of the semiconductor device. Thus, a small “α” is desired while the semiconductor device is downsized.

### Advantages of P-Type Semiconductor Substrate Sub1

The p-type semiconductor substrate SUB1 is used in the first related art. Thereby, the first related art can suppress the “substrate injection.” The p-type semiconductor substrate SUB1 has a relatively high boron concentration. This means that the resistance value of the p-type semiconductor substrate SUB1 is low. That is, the base resistance can be lowered in the first related art. Thereby, the base-emitter voltage caused when current flows into the base resistance is less likely to increase. This means that the base-emitter voltage is less likely to exceed a predetermined voltage. That is, the parasitic bipolar transistor Tr1 is less likely to be turned ON. Thus, the use of the p-type semiconductor substrate SUB1 can suppress the “substrate injection” caused when the parasitic bipolar transistor Tr1 is turned ON.

As described above, the use of the p-type semiconductor substrate SUB1 can suppress the “substrate injection.” However, the first related art using the p-type semiconductor substrate SUB1 has disadvantages.

### Room to be Improved in First Related Art

For example, as illustrated in FIG. 5, the first related art uses the p-type semiconductor substrate SUB1, and thus, needs the p-type epitaxial layer EPI1 and the p-type epitaxial layer EPI2. This is because the n-type buried layer 20 is difficult to be formed in the p-type semiconductor substrate SUB1 by doping of a donor (n-type impurity) into the p-type semiconductor substrate SUB1 with a high acceptor concentration. That is, this is because it is easier to form the p-type epitaxial layer EPI1 with a lower acceptor concentration than that of the p-type semiconductor substrate SUB1 on the p-type semiconductor substrate SUB1, and then, form the n-type buried layer 20 by doping of the donor (n-type impurity) into the p-type epitaxial layer EPI1.

Thus, the first related art using the p-type semiconductor substrate SUB1 needs two epitaxial growth steps. Thereby, the epitaxial growth step needs to be performed a plurality of times (twice) in the first related art. Consequently, the first related art has risks of the complicated manufacturing steps and the increase in the manufacturing cost of the semiconductor device.

Therefore, the following second related art has been discussed.

### DESCRIPTION OF SECOND RELATED ART

The “second related art” in the present specification is not a publicly-known technique but a technique having a problem found by the present inventors and being a precondition of the present disclosure.

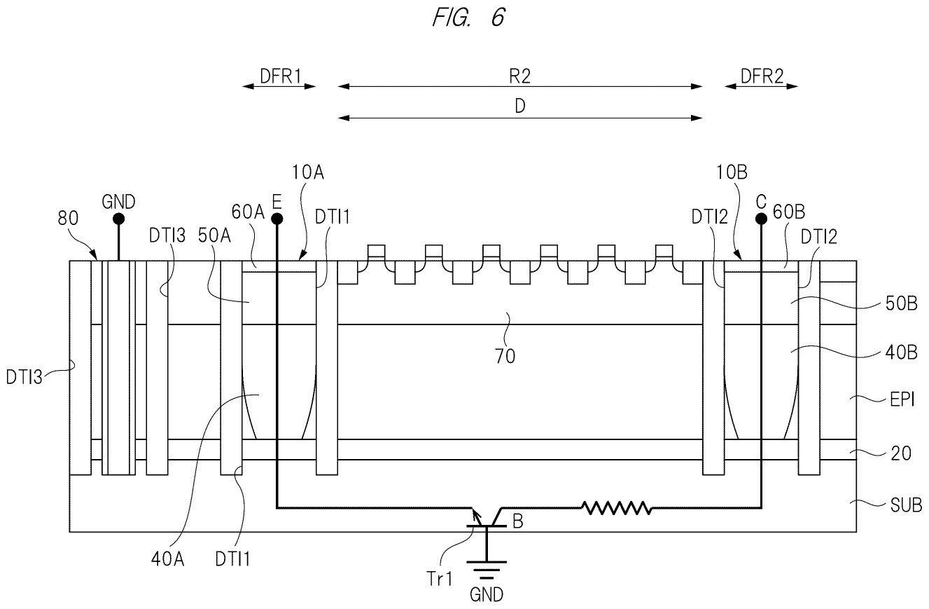

A configuration of a semiconductor device according to the second related art of FIG. 6 is almost similar to the configuration of the semiconductor device according to the first related art of FIG. 5. To the contrary, while the p-type semiconductor substrate SUB1 is used in the first related art, the p-type semiconductor substrate SUB is used in the second related art. For example, the p-type semiconductor substrate SUB is doped with boron (B) as the acceptor. The concentration of boron is, for example, equal to or higher than 0.3×10¹⁶ (1/cm³) and equal to or lower than 1×10¹⁶ (1/cm³).

Thereby, in the semiconductor device according to the second related art, it is unnecessary to form the two p-type epitaxial layers EPI1 and EPI2 as described in the first related art. That is, only one p-type epitaxial layer EPI is formed in the semiconductor device according to the second related art.

Thus, the number of times of the epitaxial growth step to be performed can be only one in the second related art. Thereby, the steps of manufacturing the semiconductor device in the second related art can be made simpler than those of the first related art. Additionally, the number of times of the epitaxial growth step to be performed can be decreased in the second related art, thereby reducing the manufacturing cost of the semiconductor device. Since the p-type semiconductor substrate SUB is used in the second related art, the increase in the manufacturing cost in the first related art can be suppressed.

### Room to be Improved in Second Related Art

The p-type semiconductor substrate SUB is used in the second related art. The p-type semiconductor substrate SUB has a lower boron concentration than that of the first related art, and thus, has a higher resistance value. For example, the resistance value of the p-type semiconductor substrate SUB is 100 to 1000 times higher than the resistance value of the p-type semiconductor substrate SUB1.

Thus, the base resistance of the parasitic bipolar transistor Tr1 is high in the second related art. This means that even the small current flowing between the base and the emitter causes the high base-emitter voltage. That is, the parasitic bipolar transistor Tr1 is easily turned ON due to the high base resistance in the second related art. In other words, the “substrate injection” easily occurs in the second related art.

In this regard, in order to suppress the “substrate injection”, the increase in the distance D between the stacked structure 10A and the stacked structure 10B is discussed. Thereby, the “α” can be decreased. However, the increase in the distance D increases the size of the semiconductor device. Thus, the small “α” is desired without the increase in the distance D.

From the above, both the first related art and the second related art are difficult to meet both the following requirements (1) and (2).

The requirement (1) is to form single p-type epitaxial layer in the semiconductor device. If the requirement (1) is met, the epitaxial growth step can be reduced, thereby simplifying the manufacturing steps and reducing the manufacturing cost of the semiconductor device.

The requirement (2) is to decrease the “a” without the increase in the distance D. If the requirement (2) is met, the operation failure in the circuit caused by the “substrate injection” can be suppressed without the increase in the size of the semiconductor device.

Therefore, in order to meet both the requirement (1) and the requirement (2), the present embodiment is with a devisal for the configuration of the semiconductor device.

### Basic Concept of Embodiment

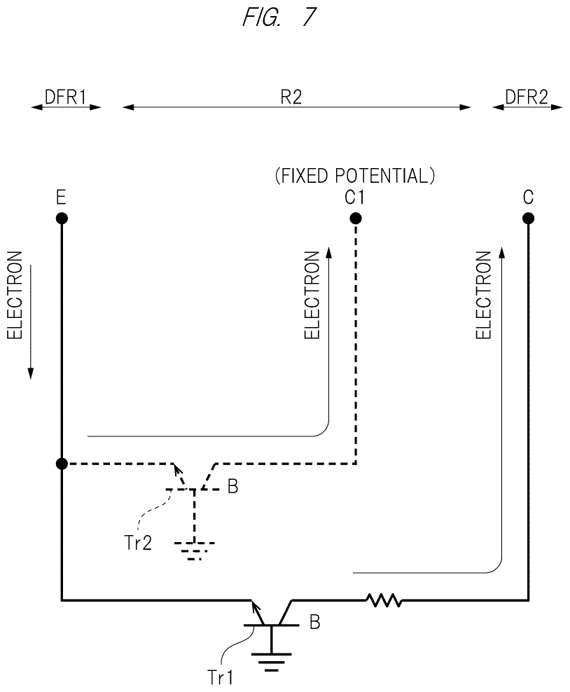

The basic concept in FIG. 7 is a devisal for the configuration of the non-element forming region R2 to form not only the parasitic bipolar transistor Tr1 but also a parasitic bipolar transistor Tr2. That is, the basic concept is a devisal for the configuration of the semiconductor device to form a collector of the parasitic bipolar transistor Tr2 in the non-element forming region R2. Thereby, the “a” can be decreased according to the basic concept. That is, the operation failure in the circuit caused by the “substrate injection” can be suppressed according to the basic concept.

For example, the first related art and the second related art do not include the parasitic bipolar transistor Tr2. Thus, if negative potential noise is input from the outside into the element forming region DFR1, the parasitic bipolar transistor Tr1 is turned ON, and thus, a plurality of electrons flow from the element forming region DFR1 (the emitter E) into the element forming region DFR2 (the collector C) as illustrated in FIG. 7. At this time, if more electrons flow into the collector C, the “α” increases. The increase in the “α” easily causes the operation failure in the circuit.

To the contrary, in the basic concept, not only the parasitic bipolar transistor Tr1 but also the parasitic bipolar transistor Tr2 are formed. Thereby, when negative potential noise is input from the outside into the element forming region DFR1, both the parasitic bipolar transistor Tr1 and the parasitic bipolar transistor Tr2 are turned ON. Consequently, a plurality of electrons flowing from the element forming region DFR1 (the emitter E) into the p-type semiconductor substrate (the base B) flow into the element forming region DFR2 (the collector C) and the non-element forming region R2 (the collector C1). Thereby, an amount of the electrons flowing into the element forming region DFR2 (the collector C) is decreased by an amount of the electrons flowing into the non-element forming region R2 (the collector C1). That is, the “α” decreases.

As described above, according to the basic concept, the “α” can be decreased by the devisal for the configuration of the non-element forming region R2 to form not only the parasitic bipolar transistor Tr1 but also the parasitic bipolar transistor Tr2. Thus, the operation failure in the circuit caused by the “substrate injection” can be suppressed according to the basic concept.

### Typified Aspect

### Configuration of Semiconductor Device

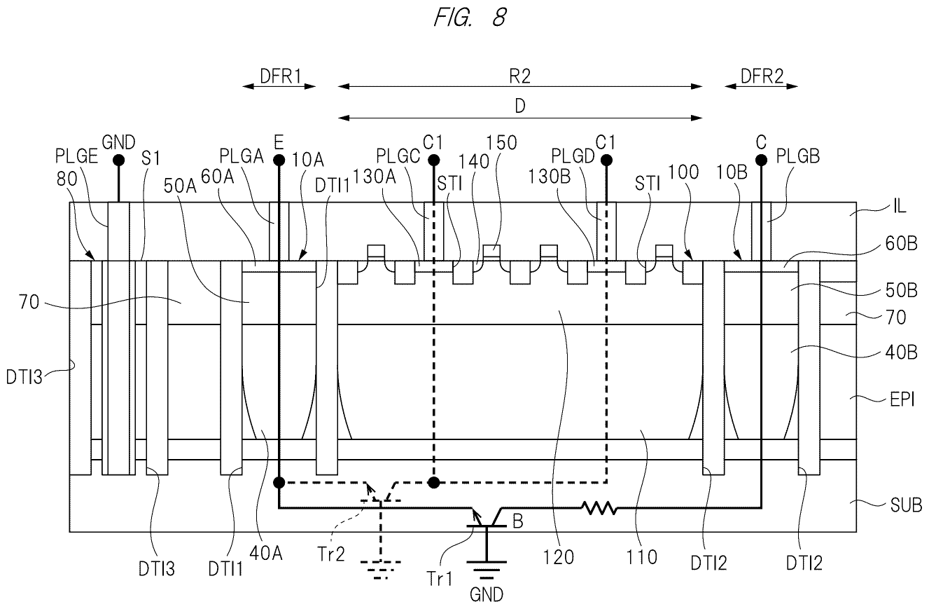

As illustrated in FIG. 8, a semiconductor device includes the p-type semiconductor substrate SUB, the n-type buried layer 20, the p-type epitaxial layer EPI, the p-type well 70, the deep trench DTI1, the deep trench DTI2, the deep trench DTI3, the trench STI, the stacked structure 10A, the stacked structure 10B, a dummy field structure 100, the GND structure 80, the interlayer insulating film IL, a plug PLGA, a plug PLGB, a plug PLGC, a plug PLGD, and a plug PLGE.

The semiconductor device further includes the element forming region DFR1, the element forming region DFR2, and the non-element forming region R2. Although not illustrated in FIG. 8, for example, the element forming region DFR1 is surrounded by the non-element forming region R2 in plan view. The element forming region DFR2 is surrounded by the non-element forming region R2 in plan view.

The p-type semiconductor substrate SUB is doped with boron as the acceptor. The concentration of boron is equal to or higher than 0.3×10¹⁶ (1/cm³) and equal to or lower than 2.0×10¹⁶ (1/cm³). That is, the concentration of the boron with which the p-type semiconductor substrate SUB is doped is, for example, lower than the concentration of boron with which the p-type semiconductor substrate SUB1 is doped in the first related art. Consequently, the resistance value of the p-type semiconductor substrate SUB is higher than that of the p-type semiconductor substrate SUB1. Specifically, the resistance value of the p-type semiconductor substrate SUB is about 100 to 1000 times higher than the resistance value of the p-type semiconductor substrate SUB1.

The p-type epitaxial layer EPI is formed on the p-type semiconductor substrate SUB. The n-type buried layer 20 is formed in the p-type semiconductor substrate SUB or the p-type epitaxial layer EPI.

Although not specifically illustrated, the element forming region DFR1 is surrounded by the deep trench DTI1 in plan view. The stacked structure 10A is formed in the element forming region DFR1 in FIG. 8. Although not specifically illustrated, the element forming region DFR2 is surrounded by the deep trench DTI2 in plan view. The stacked structure 10B is formed in the element forming region DFR2. The non-element forming region R2 is in contact with both the deep trench DTI1 and the deep trench DTI2.

The dummy field structure 100 is formed in the non-element forming region R2.

The p-type well 70 is formed in the p-type epitaxial layer EPI on the right side of the deep trench DTI2 of FIG. 8. The p-type well 70 is formed in the p-type epitaxial layer EPI on the left side of the deep trench DTI1 of FIG. 8. The deep trench DTI3 is formed to be in contact with the p-type well 70. The GND structure 80 is formed to be surrounded by the deep trench DTI3.

The GND structure 80 is surrounded by the deep trench DTI3 in plan view. As illustrated in FIG. 8, the GND structure 80 includes a trench reaching from an upper surface S1 of the p-type epitaxial layer EPI to the p-type epitaxial layer EPI1, and a conductive material (such as polysilicon) buried in the trench. Thereby, the GND potential (0 V) can be supplied to the p-type semiconductor substrate SUB. That is, the GND structure 80 has a function to supply the GND potential to the p-type semiconductor substrate SUB.

The deep n-type well 40A, the deep n-type well 40B, the n-type well 50A, the n-type well 50B, the n-type diffusion layer 60A, the n-type diffusion layer 60B, the p-type well 70, a deep n-type well 110, an n-type well 120, a first n-type semiconductor region 140, a second n-type semiconductor region 130A, a second n-type semiconductor region 130B, the deep trench DTI1, the deep trench DTI2, the deep trench DTI3, and the trench STI are formed in the p-type epitaxial layer EPI.

The deep trench DTI1, the deep trench DTI2, and the deep trench DTI3 penetrate through the n-type buried layer 20. An insulating material such as silicon oxide is buried in the deep trench DTI1, the deep trench DTI2, and the deep trench DTI3.

The stacked structure 10A includes the deep n-type well 40A, the n-type well 50A, and the n-type diffusion layer 60A. Specifically, the deep n-type well 40A, the n-type well 50A, and the n-type diffusion layer 60A are formed in the p-type epitaxial layer EPI. The n-type well 50A is formed on the deep n-type well 40A. The n-type diffusion layer 60A is formed on the n-type well 50A. The stacked structure 10A is configured of an n-type semiconductor stacked structure as described above.

The stacked structure 10A has the following configuration expressed with the structures of FIGS. 1 to 3. That is, the stacked structure 10A includes the first n-type well (NW1, NW3, NW6), the second n-type well (NW2, NW4, NW7), and the first n-type diffusion layer (NR, CR, BR1). The first n-type well, the second n-type well, and the first n-type diffusion layer are formed in the element forming region DFR1. The first n-type well is formed on the n-type buried layer 20. The second n-type well is included in the first n-type well. The first n-type diffusion layer is included in the second n-type well.

The stacked structure 10B includes the deep n-type well 40B, the n-type well 5 GB, and the n-type diffusion layer 60B. Specifically, the deep n-type well 40B, the n-type well 5 GB, and the n-type diffusion layer 60B are formed in the p-type epitaxial layer EPI. The n-type well 50B is formed on the deep n-type well 40B. The n-type diffusion layer 60B is formed on the n-type well 50B. The stacked structure 10B is configured of an n-type semiconductor stacked structure as described above.

The stacked structure 10B has the following configuration expressed with the structures of FIGS. 1 to 3. That is, the stacked structure 10B includes the third n-type well (NW1, NW3, NW6), the fourth n-type well (NW2, NW4, NW7), and the second n-type diffusion layer (NR, CR, BR1). The third n-type well, the fourth n-type well, and the second n-type diffusion layer are formed in the element forming region DFR2. The third n-type well is formed on the n-type buried layer 20. The fourth n-type well is included in the third n-type well. The second n-type diffusion layer is included in the fourth n-type well.

The dummy field structure 100 includes the deep n-type well 110, the n-type well 120, the trench STI, a conductor layer 150, the first n-type semiconductor region 140, the second n-type semiconductor region 130A, and the second n-type semiconductor region 130B. The dummy field structure 100 is formed in the non-element forming region R2.

The n-type well 120 is formed in the p-type epitaxial layer EPI. The n-type well 120 includes a first region RA and a second region RB.

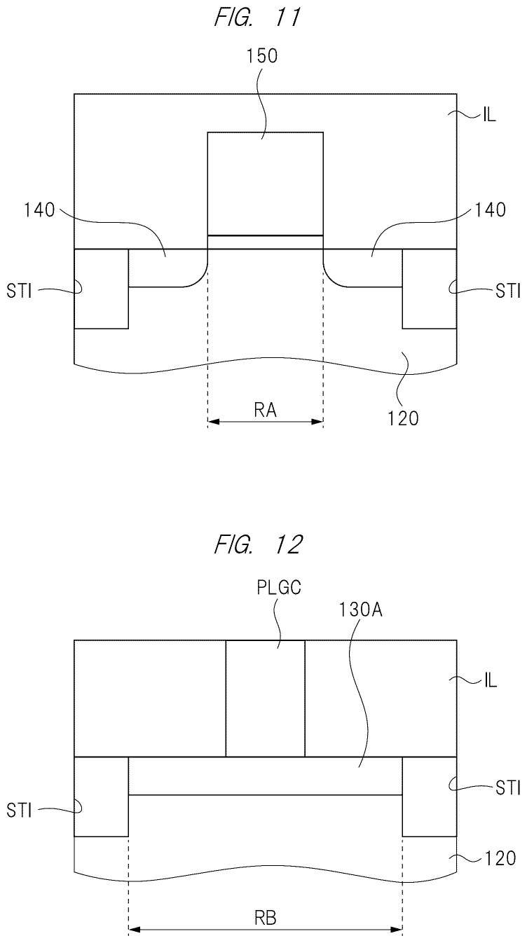

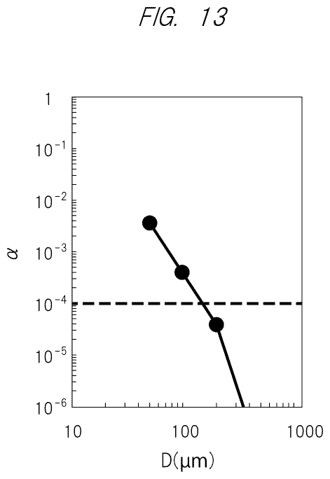

The “first region RA” in the present specification is illustrated in FIG. 11 as a region where the conductor layer 150 is formed on the n-type well 120 within the region of the n-type well 120. The “second region RB” in the present specification is illustrated in FIG. 12 as a region where the second n-type semiconductor region 130A or the second n-type semiconductor region 130B is formed inside the n-type well 120 within the region of the n-type well 120.

The deep n-type well 110 is arranged between the n-type buried layer 20 and the n-type well 120. The deep n-type well 110 is connected to the n-type buried layer 20 and the n-type well 120.

The trench STI has a bottom surface in the n-type well 120. To the contrary, the deep trench DTI1 and the deep trench DTI2 penetrate through the n-type buried layer 20 formed under the n-type well 120. Thus, the trench STI is shallower than the deep trench DTI1 and the deep trench DTI2.

The technical significance of forming the trench STI in the non-element forming region R2 is as follows. For example, a plurality of transistors are formed in the element forming region DFR1 and the element forming region DFR2. Element isolation regions are formed in the element forming region DFR1 and the element forming region DFR2 in order to electrically isolate the transistors from each other. The element isolation region is formed by, for example, burying an insulating material in the trench. The process of forming the element isolation regions includes a chemical mechanical polishing (CMP) process. The density of trenches is to be uniform over an entire surface to be polished in order to improve flatness of the surface to be polished in the CMP process. This is because non-uniformity of the density of trenches causes “dishing” in which a region with the low density of trenches is excessively polished.

Thereby, the trench STI is formed also in the non-element forming region R2 in order to suppress the “dishing” caused in the CMP process. That is, the technical significance of forming the trench STI also in the non-element forming region R2 is to make the density of trenches STI uniform over the entire surface to be polished. By the formation of the trench STI also in the non-element forming region R2, the “dishing” caused in the CMP process can be suppressed.

The conductor layer 150 is formed on the n-type well 120. The conductor layer 150 is made of, for example, a polysilicon film.

For example, a plurality of metal oxide semiconductor field effect transistors (MOSFETs) are formed in the element forming region DFR1 and the element forming region DFR2. Each of the MOSFETs includes a gate electrode, and thus, a plurality of gate electrodes are arranged in the element forming region DFR1 and the element forming region DFR2. To the contrary, a MOSFET is not formed in the non-element forming region R2. Thereby, a gate electrode is not formed in the non-element forming region R2. Thus, the density of gate electrodes is non-uniform.

The interlayer insulating film IL is formed to cover the gate electrodes as illustrated in FIG. 8. The CMP process is performed on the upper surface of the interlayer insulating film IL in order to flatten the upper surface of the interlayer insulating film IL. Thus, the density of gate electrodes is to be made uniform in order to improve flatness of the upper surface of the interlayer insulating film IL.

Therefore, the conductor layer 150 is formed in the non-element forming region R2. The conductor layer 150 functions as a dummy gate electrode. That is, the conductor layer 150 is formed in the non-element forming region R2 in order to suppress the “dishing” of the interlayer insulating film IL.

For example, a gate electrode is connected to a plug in order to apply a gate voltage to the gate electrode. To the contrary, the conductor layer 150 is a dummy gate electrode not functioning as the gate electrode. Thus, it is unnecessary to apply the gate voltage to the conductor layer 150. Therefore, the conductor layer 150 is arranged not to be connected to a plug.

The first n-type semiconductor region 140 is formed in the n-type well 120. The first n-type semiconductor region 140 is formed to be shallower than the bottom surface of the trench STI. The first n-type semiconductor region 140 is in contact with the trench STI. The impurity concentration of the first n-type semiconductor region 140 is higher than the impurity concentration (donor concentration) of the n-type well 120.

The second n-type semiconductor region 130A is formed in the n-type well 120. The second n-type semiconductor region 130A is formed to be shallower than the bottom surface of the trench STI. The second n-type semiconductor region 130A is in contact with the trench STI. The impurity concentration of the second n-type semiconductor region 130A is higher than the impurity concentration (donor concentration) of the n-type well 120.

The second n-type semiconductor region 130B is formed in the n-type well 120. The second n-type semiconductor region 130B is formed to be shallower than the bottom surface of the trench STI. The second n-type semiconductor region 130B is in contact with the trench STI. The impurity concentration of the second n-type semiconductor region 130B is higher than the impurity concentration (donor concentration) of the n-type well 120.

The second n-type semiconductor region 130A and the second n-type semiconductor region 130B are formed in the non-element forming region R2 as described above. That is, the second n-type semiconductor regions (130A and 130B) are formed in the non-element forming region R2.

As illustrated in FIG. 8, the plug PLGA, the plug PLGB, the plug PLGC, the plug PLGD, and the plug PLGE are formed in the interlayer insulating film IL. The interlayer insulating film IL is made of, for example, a silicon oxide film.

The plug PLGA penetrates through the interlayer insulating film IL. The plug PLGA is arranged on the n-type diffusion layer 60A. The plug PLGA is connected to the n-type diffusion layer 60A.

The plug PLGB penetrates through the interlayer insulating film IL. The plug PLGB is arranged on the n-type diffusion layer 60B. The plug PLGB is connected to the n-type diffusion layer 60B.

The plug PLGC penetrates through the interlayer insulating film IL. The plug PLGC is arranged on the second n-type semiconductor region 130A. The plug PLGC is connected to the second n-type semiconductor region 130A. Thereby, a fixed potential is supplied to the second n-type semiconductor region 130A via the plug PLGC. The fixed potential is, for example, ground potential.

The plug PLGD penetrates through the interlayer insulating film IL. The plug PLGD is arranged on the second n-type semiconductor region 130B. The plug PLGD is connected to the second n-type semiconductor region 130B. Thereby, a fixed potential is supplied to the second n-type semiconductor region 130B via the plug PLGD. The fixed potential is, for example, ground potential.

The plug PLGE penetrates through the interlayer insulating film IL. The plug PLGE is arranged on the GND structure 80. The plug PLGE is connected to the GDN structure 80.

As illustrated with thick solid line in FIG. 8, the stacked structure 10A, the p-type semiconductor substrate SUB, and the stacked structure 10B configure the parasitic bipolar transistor Tr1.

As illustrated with thick dotted line in FIG. 8, the stacked structure 10A, the p-type semiconductor substrate SUB, and the dummy field structure 100 configure the parasitic bipolar transistor Tr2.

The stacked structure 10A functions as the emitter of the parasitic bipolar transistor Tr1 and the emitter of the parasitic bipolar transistor Tr2. The p-type semiconductor substrate SUB functions as the base of the parasitic bipolar transistor Tr1 and the base of the parasitic bipolar transistor Tr2. The stacked structure 10B functions as the collector of the parasitic bipolar transistor Tr1. The dummy field structure 100 functions as the collector of the parasitic bipolar transistor Tr2. Thereby, the basic concept is typified.

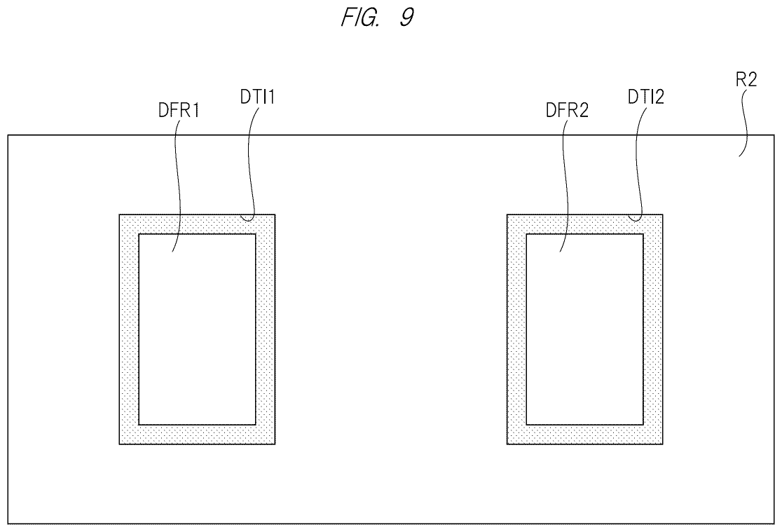

As illustrated in FIG. 9, the element forming region DFR1 and the element forming region DFR2 are surrounded by the non-element forming region R2 in plan view. That is, the element forming region DFR1 and the element forming region DFR2 are included in the non-element forming region R2 in plan view.

In FIG. 9, the element forming region DFR1 is surrounded by the deep trench DTI1 in plan view. That is, the region surrounded by the deep trench DTI1 configures the element forming region DFR1. The element forming region DFR2 is surrounded by the deep trench DTI2 in plan view. That is, the region surrounded by the deep trench DTI2 configures the element forming region DFR2.

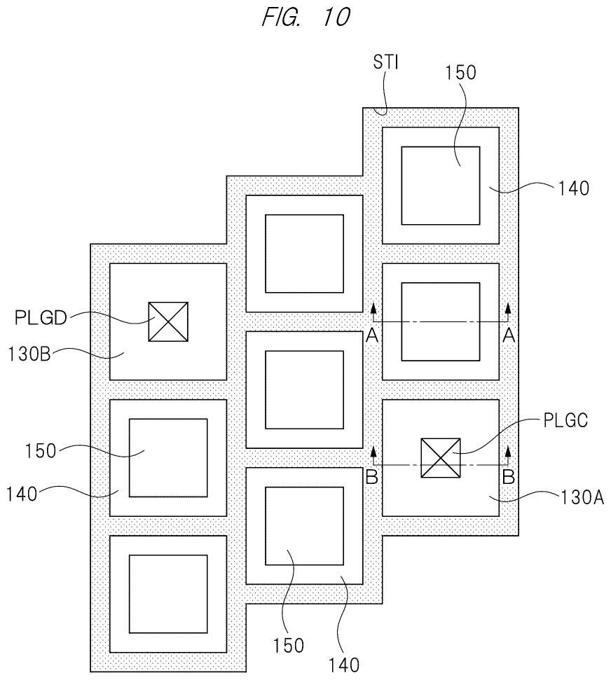

As illustrated in FIG. 10, the trench STI has a grid-like plane shape. The conductor layer 150 is included in the trench STI in plan view. That is, the conductor layer 150 is surrounded by the trench STI in plan view. The first n-type semiconductor region 140 is formed between the trench STI and the conductor layer 150 in plan view. The first n-type semiconductor region 140 is surrounded by the trench STI in plan view. The first n-type semiconductor region 140 surrounds the conductor layer 150 in plan view.

The conductor layer 150 and the first n-type semiconductor region 140 are formed in a part of the plurality of regions surrounded by the trench STI as described above.

In FIG. 10, the plurality of regions surrounded by the trench STI include a region where the conductor layer 150 is not formed. In this region, for example, the second n-type semiconductor region 130A or the second n-type semiconductor region 130B is formed. The second n-type semiconductor region 130A is surrounded by the trench STI in plan view. Similarly, the second n-type semiconductor region 130B is surrounded by the trench STI in plan view. The plug PLGC is arranged on the second n-type semiconductor region 130A. The second n-type semiconductor region 130A is connected to the plug PLGC. Similarly, the plug PLGD is arranged on the second n-type semiconductor region 130B. The second n-type semiconductor region 130B is connected to the plug PLGD.

The second n-type semiconductor region 130A or the second n-type semiconductor region 130B is formed in the other part of the plurality of regions surrounded by the trench STI as described above.

As illustrated in FIG. 11, the conductor layer 150 is formed on the first region RA in the n-type well 120. The first n-type semiconductor region 140 is formed in the n-type well 120 between the first region RA and the trench STI. The first n-type semiconductor region 140 surrounds the conductor layer 150 in plan view as understood from FIG. 10. In other words, the first n-type semiconductor region 140 surrounds the first region RA.

As illustrated in FIG. 12, the second n-type semiconductor region 130A is formed in the second region RB in the n-type well 120. The second n-type semiconductor region 130A is surrounded by the trench STI in plan view as understood from FIG. 10. As illustrated in FIG. 12, the plug PLGC is arranged on the second n-type semiconductor region 130A. The second n-type semiconductor region 130A is connected to the plug PLGC. Thereby, a fixed potential can be supplied to the second n-type semiconductor region 130A via the plug PLGC.

The semiconductor device in the typified aspect is configured as described above.

### Features of Typified Aspect

The first feature of the typified aspect is that, for example, the p-type semiconductor substrate SUB is used as illustrated in FIG. 8. Thereby, the number of the p-type epitaxial layer formed on the p-type semiconductor substrate SUB can be one. Thus, according to the first feature of the typified aspect, the epitaxial growth step can be reduced thereby to simplify the manufacturing steps and to reduce the manufacturing cost of the semiconductor device.

The second feature of the typified aspect is that, for example, the dummy field structure 100 is formed in the non-element forming region R2 such that not only the parasitic bipolar transistor Tr1 but also the parasitic bipolar transistor Tr2 is formed as illustrated in FIG. 8. The dummy field structure 100 includes the deep n-type well 110, the n-type well 120, the trench STI, the conductor layer 150, the first n-type semiconductor region 140, the second n-type semiconductor region 130A, and the second n-type semiconductor region 130B as illustrated in FIG. 8.

Thereby, the collector of the parasitic bipolar transistor Tr2 can be formed in the non-element forming region R2. Thus, according to the typified aspect, not only the parasitic bipolar transistor Tr1 but also the parasitic bipolar transistor Tr2 are formed in the semiconductor device.

From the above, when negative potential noise is input from the outside into the element forming region DFR1, both the parasitic bipolar transistor Tr1 and the parasitic bipolar transistor Tr2 are turned ON. Consequently, the plurality of electrons flowing from the element forming region DFR1 (the emitter E) into the p-type semiconductor substrate (the base B) flow into the element forming region DFR2 (the collector C) and the non-element forming region R2 (the collector C1). Thereby, an amount of the electrons flowing into the element forming region DFR2 (the collector C) is decreased by an amount of the electrons flowing into the non-element forming region R2 (the collector C1). That is, the “α” decreases.

As described above, the “α” can be decreased by the formation of the dummy field structure in the non-element forming region R2. Thus, the operation failure in the circuit caused by the “substrate injection” can be suppressed according to the second feature.

Particularly, the p-type well 70 is not formed in the non-element forming region R2 in the typified aspect. Thus, the area of the collector of the parasitic bipolar transistor Tr2 can be increased. The plurality of second n-type semiconductor regions (130A and 130B) are formed in the typified aspect. A fixed potential is supplied to the plurality of second n-type semiconductor regions (130A and 130B) via the plugs (PLGC and PLGD), respectively. Thereby, the typified aspect includes a plurality of paths configured to extract the electrons from the parasitic bipolar transistor Tr2. Consequently, the amount of the electrons flowing into the non-element forming region R2 (the collector C1) can be increased. This means that the amount of the electrons flowing into the element forming region DFR2 (the collector C) can be decreased. Thereby, the “α” can be decreased by the typified aspect.

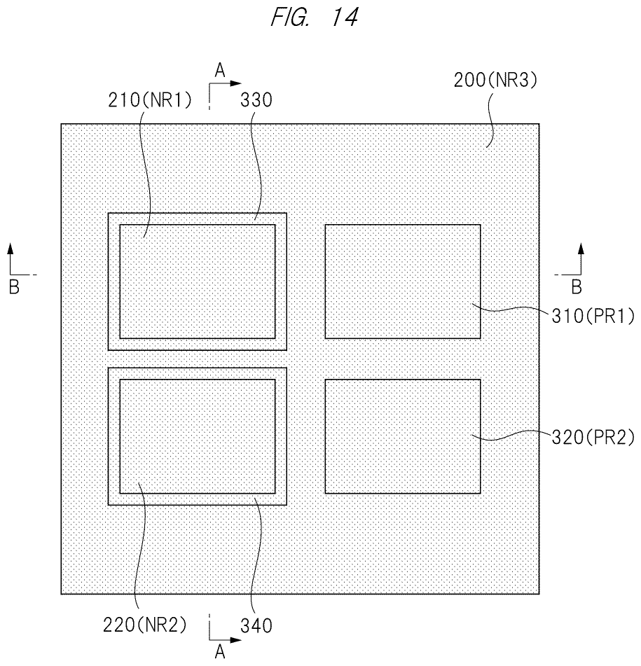

As understood from FIG. 13, a relationship “α≤10⁻⁴” can be achieved at the distance “D≥150 μm” in the typified aspect. That is, when first current flows in the emitter (E) while second current flows in the collector (C) of the parasitic bipolar transistor Tr1 under a condition “second current/first current=α”, the relationship “α≤10⁻⁴” can be achieved at the distance “D≥150 μm”. Thus, the “α” can be effectively decreased by the typified aspect even if the distance D is not larger than 150 m.

From the above, with the semiconductor device according to the typified aspect, the manufacturing steps can be simplified, the manufacturing cost of the semiconductor device can be reduced, and the “substrate injection” can be suppressed without the increase in the size of the semiconductor device.

### Modification Example

In the typified aspect, the example of use of the p-type semiconductor substrate SUB has described. The technical concept of the present embodiment is not limited thereto, and is also applicable to, for example, a semiconductor device using the p-type semiconductor substrate SUB1.

As described in the first related art, the parasitic bipolar transistor Tr1 is difficult to be turned ON in the semiconductor device using the p-type semiconductor substrate SUB1. Thus, in the case of the use of the p-type semiconductor substrate SUB1, the “substrate injection” caused when the parasitic bipolar transistor Tr1 is turned ON is difficult to be caused.

However, when the technical concept of the present embodiment is applied to the semiconductor device using the p-type semiconductor substrate SUB1, the “substrate injection” can be reduced even if the parasitic bipolar transistor Tr1 is turned ON.

Therefore, the technical concept of the present embodiment is also effectively applicable to the semiconductor device using the p-type semiconductor substrate SUB1 in order to improve the performance of the semiconductor device.

### Application Example

In FIG. 14, a semiconductor device includes an element forming region NR1, an element forming region NR2, an element forming region PR1, an element forming region PR2, and a non-element forming region NR3. The semiconductor device further includes an n-type well 200, an n-type well 210, an n-type well 220, a p-type well 310, a p-type well 320, a p-type well 330, and a p-type well 340.

As illustrated in FIG. 14, the n-type well 210, the n-type well 220, the p-type well 310, and the p-type well 320 are formed at the center of the semiconductor device. To the contrary, the n-type well 200 is formed at the periphery surrounding the center of the semiconductor device.

The n-type well 210 is formed in the element forming region NR1. The n-type well 210 is surrounded by the p-type well 330. The p-type well 330 is surrounded by the n-type well 200. For example, a p-type MOSFET is formed in the n-type well 210.

The n-type well 220 is formed in the element forming region NR2. The n-type well 220 is surrounded by the p-type well 340. The p-type well 340 is surrounded by the n-type well 200. For example, a p-type MOSFET is formed in the n-type well 220.

The p-type well 310 is formed in the element forming region PR1. The p-type well 310 is surrounded by the n-type well 200. For example, an n-type MOSFET is formed in the p-type well 310.

The p-type well 320 is formed in the element forming region PR2. The p-type well 320 is surrounded by the n-type well 200. For example, an n-type MOSFET is formed in the p-type well 320.

The n-type well 200 is formed in the non-element forming region NR3. The n-type well 200 surrounds the p-type well 330 surrounding the n-type well 210. Similarly, the n-type well 200 surrounds the p-type well 340 surrounding the n-type well 220. The n-type well 200 surrounds the p-type well 310. Similarly, the n-type well 200 surrounds the p-type well 320. An element is not formed in the n-type well 200.

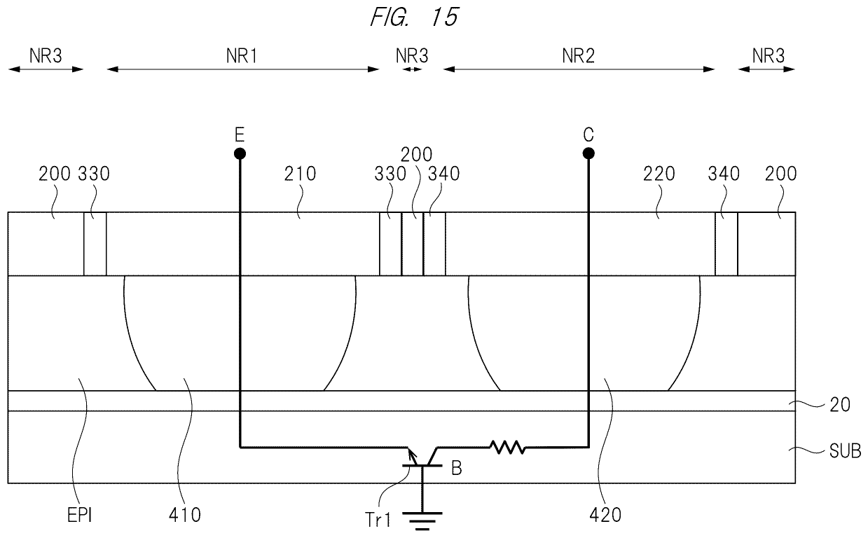

In FIG. 15, the semiconductor device includes the p-type semiconductor substrate SUB, the n-type buried layer 20, the p-type epitaxial layer EPI, the n-type well 200, the n-type well 210, the n-type well 220, the p-type well 330, the p-type well 340, a deep n-type well 410, and a deep n-type well 420. As illustrated in FIG. 15, the parasitic bipolar transistor Tr1 is formed between the element forming region NR1 and the element forming region NR2.

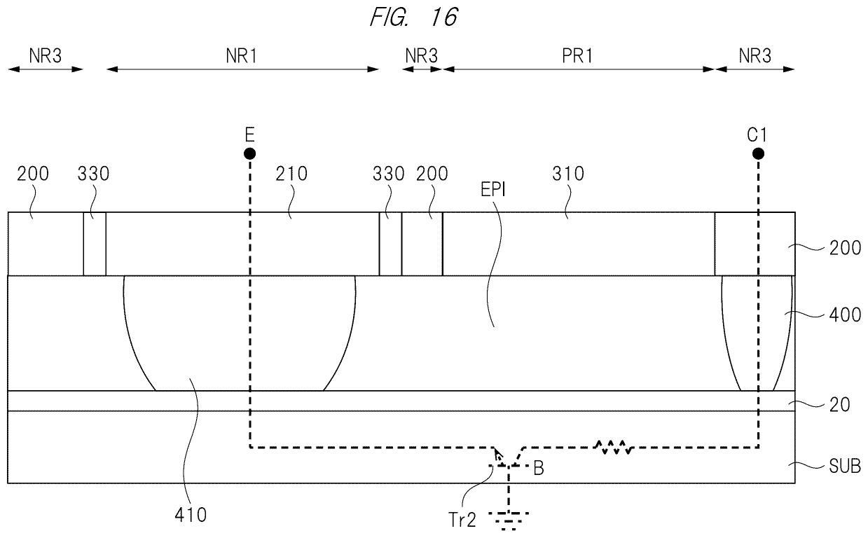

In FIG. 16, the semiconductor device includes the p-type semiconductor substrate SUB, the n-type buried layer 20, the p-type epitaxial layer EPI, the n-type well 200, the n-type well 210, the p-type well 310, the p-type well 330, a deep n-type well 400, and the deep n-type well 410.

The p-type semiconductor substrate SUB is doped with boron as the acceptor. The concentration of boron is equal to or higher than 0.3×10¹⁶ (1/cm³) and equal to or lower than 2.0×10¹⁶ (1/cm³).

The p-type epitaxial layer EPI is formed on the p-type semiconductor substrate SUB. The n-type buried layer 20 is formed in the p-type semiconductor substrate SUB or the p-type epitaxial layer EPI.

The n-type well 200 is formed in the non-element forming region NR3. The n-type well 200 is formed in the p-type epitaxial layer EPI.

The deep n-type well 400 is arranged between the n-type buried layer 20 and the n-type well 200. The deep n-type well 400 is connected to the n-type buried layer 20 and the n-type well 200.

The n-type well 210 is formed in the element forming region NR1. The n-type well 210 is formed in the p-type epitaxial layer EPI.

The deep n-type well 410 is arranged between the n-type buried layer 20 and the n-type well 210. The deep n-type well 410 is connected to the n-type buried layer 20 and the n-type well 210.

The n-type well 210 is surrounded by the p-type well 330. The p-type well 330 has a function to electrically isolate the n-type well 200 and the n-type well 210.

The p-type well 310 is formed in the element forming region PR1. The p-type well 310 is formed in the p-type epitaxial layer EPI. The p-type well 310 is surrounded by the n-type well 200.

As illustrated in FIG. 16, the parasitic bipolar transistor Tr2 is formed between the element forming region NR1 and the non-element forming region NR3.

As described above, also in the application example, the parasitic bipolar transistor Tr1 and the parasitic bipolar transistor Tr2 are formed. Thus, the application example embodies the basic concept of the present embodiment. Thereby, also in the application example, when negative potential noise is input from the outside into the element forming region NR1, both the parasitic bipolar transistor Tr1 and the parasitic bipolar transistor Tr2 are turned ON. Consequently, a plurality of electrons flowing from the element forming region NR1 (the emitter E) into the p-type semiconductor substrate (the base B) flow into the element forming region NR2 (the collector C) and the non-element forming region NR3 (the collector C1). Thereby, an amount of the electrons flowing into the element forming region NR2 (the collector C) is decreased by an amount of the electrons flowing into the non-element forming region NR3 (the collector C1). That is, the “α” decreases.

As described above, in the application example, the “a” can be decreased by the devisal for the configuration of the non-element forming region NR3. Thus, the operation failure in the circuit caused by the “substrate injection” can be also suppressed according to the application example.

In the foregoing, the invention made by the inventors of the present application has been concretely described on the basis of the embodiments. However, it is needless to say that the present invention is not limited to the foregoing embodiments, and various modifications can be made within the scope of the present invention.

What is claimed is:

1. A semiconductor device including an element forming region and a non-element forming region, the semiconductor device comprising:
a p-type semiconductor substrate;
a p-type epitaxial layer formed on the p-type semiconductor substrate;
an n-type buried layer formed in the p-type semiconductor substrate or in the p-type epitaxial layer;
an n-type well formed in the non-element forming region and in the p-type epitaxial layer, the n-type well including a first region and a second region;
a deep n-type well formed in the non-element forming region, the deep n-type well being arranged between the n-type buried layer and the n-type well, the deep n-type well being connected to the n-type buried layer and the n-type well;
a deep trench surrounding the element forming region in plan view and penetrating through the n-type buried layer;
a trench formed in the non-element forming region and having a bottom surface in the n-type well;
a conductor layer formed in the non-element forming region, the conductor layer being surrounded by the trench in plan view, the conductor layer being formed on the first region;
a first n-type semiconductor region formed in the non-element forming region, the first n-type semiconductor region being surrounded by the trench in plan view, the first n-type semiconductor region being formed in the n-type well, the first n-type semiconductor region surrounding the first region in plan view, the first n-type semiconductor region being formed to be shallower than the bottom surface of the trench;
a second n-type semiconductor region formed in the non-element forming region, the second n-type semiconductor region being surrounded by the trench in plan view, the second n-type semiconductor region being formed in the second region of the n-type well, the second n-type semiconductor region being formed to be shallower than the bottom surface of the trench; and
a plug arranged on the second n-type semiconductor region and connected to the second n-type semiconductor region,
wherein a first insulating material is buried in the deep trench,
wherein a second insulating material is buried in the trench,
wherein an impurity concentration of the first n-type semiconductor region is higher than an impurity concentration of the n-type well,
wherein an impurity concentration of the second n-type semiconductor region is higher than an impurity concentration of the n-type well, and
wherein a fixed potential is supplied to the second n-type semiconductor region via the plug.

2. The semiconductor device according to claim 1,
wherein the first n-type semiconductor region surrounds the conductor layer in plan view.

3. The semiconductor device according to claim 1,
wherein the fixed potential is ground potential.

4. The semiconductor device according to claim 1,
wherein the conductor layer is arranged not to be connected to the plug.

5. The semiconductor device according to claim 1,
wherein the element forming region includes a first element forming region and a second element forming region,
wherein the deep trench includes a first deep trench and a second deep trench, and
wherein the semiconductor device includes:
the first deep trench surrounding the first element forming region in plan view and penetrating through the n-type buried layer;
a first n-type well formed in the first element forming region and formed on the n-type buried layer;
a second n-type well formed in the first element forming region and included in the first n-type well;
a first n-type diffusion layer formed in the first element forming region and included in the second n-type well;
the second deep trench surrounding the second element forming region in plan view and penetrating through the n-type buried layer;
a third n-type well formed in the second element forming region and formed on the n-type buried layer;
a fourth n-type well formed in the second element forming region and included in the third n-type well; and
a second n-type diffusion layer formed in the second element forming region and included in the fourth n-type well.

6. The semiconductor device according to claim 5,
wherein the first element forming region is surrounded by the non-element forming region in plan view, and
wherein the second element forming region is surrounded by the non-element forming region in plan view.

7. The semiconductor device according to claim 5,
wherein each of the first n-type diffusion layer and the second n-type diffusion layer configures an n-type body contact region of a p-type LDMOSFET, a collector region of an npn-type bipolar transistor, or a base region of a lateral pnp-type bipolar transistor.

8. The semiconductor device according to claim 5,
wherein the n-type buried layer, the deep n-type well, the n-type well, and the second n-type semiconductor region, which are formed in the non-element forming region, configure a dummy field structure,
wherein the n-type buried layer, the first n-type well, the second n-type well, and the first n-type diffusion layer, which are formed in the first element forming region, configure a first stacked structure,
wherein the n-type buried layer, the third n-type well, the fourth n-type well, and the second n-type diffusion layer, which are formed in the second element forming region, configure a second stacked structure,
wherein the first stacked structure, the p-type semiconductor substrate, and the second stacked structure configure a first parasitic bipolar transistor,
wherein the first stacked structure, the p-type semiconductor substrate, and the dummy field structure configure a second parasitic bipolar transistor,
wherein the first stacked structure functions as an emitter of the first parasitic bipolar transistor and an emitter of the second parasitic bipolar transistor,
wherein the p-type semiconductor substrate functions as a base of the first parasitic bipolar transistor and a base of the second parasitic bipolar transistor,
wherein the second stacked structure functions as a collector of the first parasitic bipolar transistor, and
wherein the dummy field structure functions as a collector of the second parasitic bipolar transistor.

9. The semiconductor device according to claim 8,
wherein first current flows in the emitter,
wherein second current flows in the collector of the first parasitic bipolar transistor, and
wherein, in a case of a relationship “the second current/the first current=α”, a relationship “α≤10⁻⁴” is established.

10. The semiconductor device according to claim 1,
wherein the p-type semiconductor substrate is doped with boron, and
wherein a concentration of boron in the p-type semiconductor substrate is equal to or higher than 0.5×10¹⁹ (1/cm³) and equal to or lower than 4.0×10¹⁹ (1/cm³).

11. The semiconductor device according to claim 1,
wherein the p-type semiconductor substrate is doped with boron, and
wherein a concentration of boron in the p-type semiconductor substrate is equal to or higher than 0.3×10¹⁶ (1/cm³) and equal to or lower than 2.0×10¹⁶ (1/cm³).

12. A semiconductor device comprising:
a p-type semiconductor substrate;
a p-type epitaxial layer formed on the p-type semiconductor substrate;
an n-type buried layer formed in the p-type semiconductor substrate or in the p-type epitaxial layer;
an n-type well formed in the p-type epitaxial layer;
a deep n-type well arranged between the n-type buried layer and the n-type well, the deep n-type well being connected to the n-type buried layer and the n-type well; and
a p-type well surrounded by the n-type well in plan view.

13. The semiconductor device according to claim 12,
wherein the n-type well includes a first n-type well and a second n-type well which are electrically isolated from each other,
wherein the deep n-type well includes:
a first deep n-type well arranged between the first n-type well and the n-type buried layer, the first deep n-type well being connected to the first n-type well and the n-type buried layer; and
a second deep n-type well arranged between the second n-type well and the n-type buried layer, the second deep n-type well being connected to the second n-type well and the n-type buried layer,
wherein the first n-type well is formed in a non-element forming region, and
wherein the second n-type well is formed in an element forming region.
